(19) United States
(12) Patent Application Publication
(10) Pub. No.: US 2025/0210358 A1
(43) Pub. Date: Jun. 26, 2025

(54) CAPACITOR ELECTRODE FORMING METHOD

(71) Applicant: JUSUNG Engineering Co., Ltd., Gwangju-si, Gyeonggi-do (KR)

(72) Inventors: Jeong Soo JEON, Gwangju-Si, Gyeonggi-Do (KR); Yeon Rae KIM, Gwangju-Si, Gyeonggi-Do (KR); Cheong SON, Gwangju-Si, Gyeonggi-Do (KR); Jin Pyo OH, Gwangju-Si, Gyeonggi-Do (KR); Da Eun LEE, Gwangju-Si, Gyeonggi-Do (KR); Je Ryun LEE, Gwangju-Si, Gyeonggi-Do (KR); Jong Soo LEE, Gwangju-Si, Gyeonggi-Do (KR); Hyo Sub JUNG, Gwangju-Si, Gyeonggi-Do (KR); Chul Joo HWANG, Gwangju-Si, Gyeonggi-Do (KR)

(21) Appl. No.: 18/848,963

(22) PCT Filed: Mar. 24, 2023
(86) PCT No.: PCT/KR2023/003931

§ 371 Date: Sep. 20, 2024

(30) Foreign Application Priority Data
Mar. 29, 2022 (KR) 10-2022-0038832

(51) Int. Cl. H01L 21/285; C23C 16/44; H10D 1/68

(52) U.S. Cl. CPC H01L 21/28556; C23C 16/4408; H10D 1/692

(57) ABSTRACT

A method for forming a capacitor electrode in accordance with an exemplary embodiment includes a step of forming a TiN thin-film by injecting a source containing titanium (Ti) and a reactant containing nitrogen and a step of forming SiN thin-film by injecting a source containing silicon (Si) and a reactant containing nitrogen, and at least one of the source containing titanium (Ti) and the source containing silicon (Si) is injected a plurality of times.

Thus, in accordance with exemplary embodiments, when at least one of a lower electrode and an upper electrode of a capacitor is formed by laminating the TiN thin-film and the SiN thin-film, a deposition speed of the SiN thin film may be improved, and step coverage of the thin film may be improved.

### BACKGROUND

The present disclosure relates to a method for forming a capacitor electrode, and more particularly, to a method for forming a capacitor electrode, which is capable of improving a deposition speed.

A capacitor applied to a semiconductor device includes a lower electrode formed on a substrate, a dielectric layer formed on the lower electrode, and an upper electrode formed on the dielectric layer.

The substrate may have a trench, and the capacitor may be prepared by laminating the lower electrode, the dielectric layer, and the upper electrode on the substrate. Also, each of the upper electrode and the lower electrode is formed by laminating a TiN thin-film (titanium nitride thin-film) and a SiN thin-film (silicon nitride thin-film).

On the other hand, the SiN thin-film is formed by using SiH₄ (silane) as a source, and the SiH₄ has a low deposition speed and a low deposition rate. Thus, each of the lower electrode and the upper electrode has low step coverage, which causes characteristics of the capacitor to be degraded.

The low step coverage may be improved by allowing a thickness of each of the lower electrode and the upper electrode to increase. However, in this case, a long time is required to form the lower electrode and an upper electrode each having a target thickness.

Also, as a deposition time increases, the thickness of the lower electrode increases, and accordingly, a space in which the dielectric layer is formed inside a trench decreases. This may act as a factor that causes dielectric constant of the dielectric layer to decrease.

### RELATED ART DOCUMENT

### Patent Document

(Patent document 1) Korean Patent Registration No. 10-1110077

### SUMMARY

The present disclosure provides a method for forming a capacitor electrode capable of improving a deposition speed.

The present disclosure also provides a method for forming a capacitor electrode capable of improving step coverage.

In accordance with an exemplary embodiment, a method for forming a capacitor electrode includes: forming a TiN thin-film by injecting a source containing titanium (Ti) and a reactant containing nitrogen; and forming a SiN thin-film by injecting a source containing silicon (Si) and a reactant containing nitrogen, and at least one of the source containing titanium (Ti) and the source containing silicon (Si) is injected a plurality of times.

The forming of the TiN thin-film and the forming of the SiN thin-film may be consecutively performed.

The forming of the TiN thin-film may be consecutively performed more times than the forming of the SiN thin-film.

A ratio (T₁:T₂) of the performed number T₁ of the forming of the TiN thin-film to the performed number T₂ of the forming of the SiN thin-film may be adjusted to 1:1 to 4:1.

The source containing silicon (Si) may be a silicon (Si) gas containing hydrogen (H) or a silicon (Si) precursor containing chlorine (Cl) or a mixed gas in which the silicon (Si) gas containing hydrogen (H) and the silicon (Si) precursor containing chlorine (Cl) are mixed.

The silicon (Si) precursor containing chlorine (Cl) may be hexachlorodisilane (HCDS: Si₂Cl₆) or dichlorosilane (DCS: SiH₂Cl₂), and the silicon (Si) gas containing hydrogen (H) may be silane (SiH₄).

The forming of the SiN thin-film may include: forming a first SiN thin-film by injecting the silicon (Si) gas containing hydrogen (H); and forming a second SiN thin-film by injecting the silicon (Si) precursor containing chlorine (Cl).

A ratio of the performed number of the forming of the second SiN thin-film to the performed number of the forming of the first SiN thin-film may be adjusted to 1:3 to 3:1. Injecting a purge gas may be added between injecting different kinds of gases.

### BRIEF DESCRIPTION OF THE DRAWINGS

Exemplary embodiments may be understood in more detail from the following description taken in conjunction with the accompanying drawings, in which:

FIG. 1 is a conceptual view illustrating a capacitor in which an electrode is formed by a method for forming a capacitor electrode in accordance with exemplary embodiments;

FIG. 2 is a conceptual view illustrating a lower electrode formed on a substrate by a method in accordance with an exemplary embodiment;

FIG. 3 is a conceptual view for explaining a method for forming the lower electrode in accordance with an exemplary embodiment;

FIG. 4 is a conceptual view for explaining the method for forming the lower electrode in accordance with a modified example of an exemplary embodiment;

FIG. 5 is a conceptual view illustrating a lower electrode formed on a substrate by a method in accordance with another exemplary embodiment;

FIG. 6 is a conceptual view for explaining a method for forming the lower electrode in accordance with another exemplary embodiment;

FIG. 7 is a conceptual view for explaining a method for forming a lower electrode in accordance with yet another exemplary embodiment;

FIG. 8 is a conceptual view for explaining the method for forming the lower electrode in accordance with a modified example of yet another exemplary embodiment;

FIG. 9 is a view illustrating the lower electrode formed on the substrate by the method in accordance with exemplary embodiments; and

FIGS. 10A and 10B are views illustrating a state in which a TiN thin-film and a SiN thin-film are laminated on a substrate having a trench by the method in accordance with another exemplary embodiment.

### DETAILED DESCRIPTION OF EXEMPLARY EMBODIMENTS

Hereinafter, the exemplary embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout.

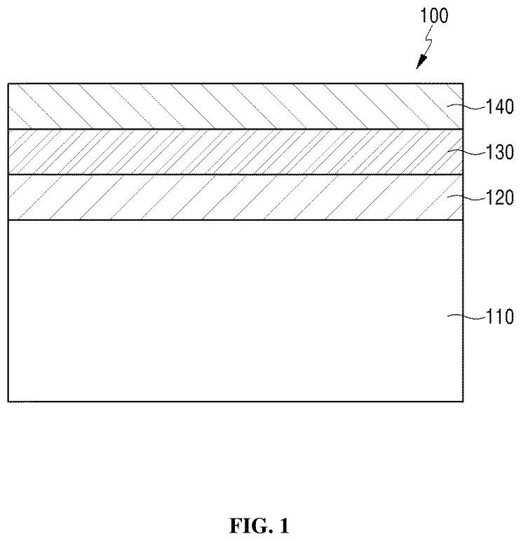

FIG. 1 is a conceptual view illustrating a capacitor in which an electrode is formed in a capacitor electrode formation method in accordance with exemplary embodiments.

Referring to FIG. 1, a capacitor 100 may include a substrate 110, a lower electrode 120 formed on the substrate 110, a dielectric layer 130 formed on the lower electrode 120, and an upper electrode 140 formed on the dielectric layer 130.

The substrate 110 may be a semiconductor substrate. More specifically, the substrate 110 may be a wafer, e.g., one of a Si wafer, a GaAs wafer, and a SiGe wafer.

The dielectric layer 130 is formed on the substrate 110. Here, the dielectric layer 130 may be made of a dielectric material containing a metal oxide. More specifically, for example, the dielectric layer 130 may be made of one of ZrO₂, Al₂O₃, TiO₂, TaO₂ and HfO₂. Also, the dielectric layer 130 may be formed by an atomic layer deposition (ALD) method or a chemical vapor deposition (CVD) method.

Each of the lower electrode 120 and the upper electrode 140 is formed by laminating a TiN thin-film and a SiN thin-film, and the TiN thin-film and the SiN thin-film are formed by the ALD method. Here, the SiN thin-film is formed by using a source including a compound containing a plurality of Si atoms. As described above, a deposition speed of the SiN thin-film may be improved, and step coverage may be improved by using a compound containing a plurality of Si atoms or a source including a compound containing a plurality of Si atoms.

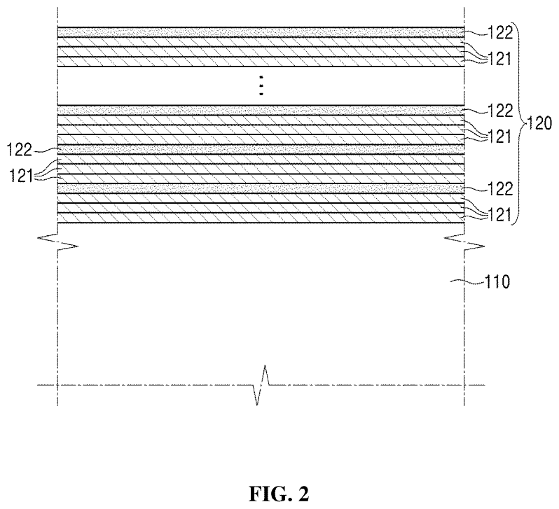

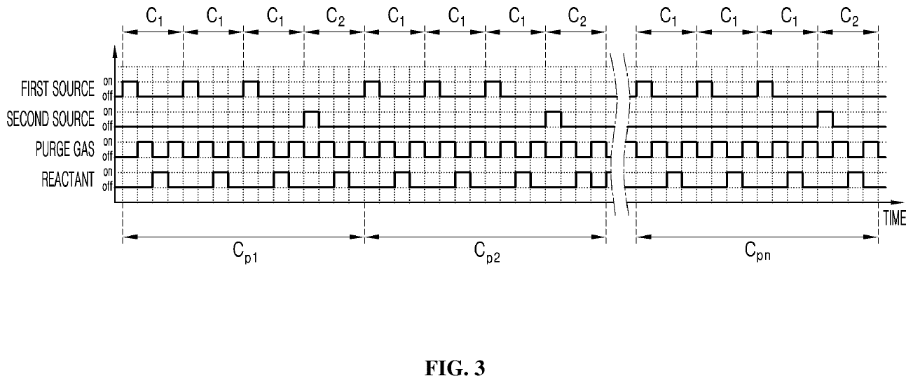

Hereinafter, a method for forming the lower electrode on a substrate by a method in accordance with an exemplary embodiment will be described with reference to FIGS. 2 and 3. Here, since the method for forming the lower electrode is the same as that for forming the upper electrode, the method for forming the lower electrode will be described, and the method for forming the upper electrode will be omitted.

FIG. 2 is a view illustrating the lower electrode formed on the substrate by the method in accordance with an exemplary embodiment. FIG. 3 is a conceptual view illustrating the method for forming the lower electrode by the method in accordance with an exemplary embodiment. Here, a term ‘on’ in FIG. 3 may represent that a gas is injected, and a term ‘off’ may represent that gas injection is stopped or terminated.

Referring to FIG. 2, a lower electrode 120 may include a TiN thin-film 121 and a SiN thin-film 122 deposited on the TiN thin-film 121. Here, the TiN thin-film 121 may be formed by the ALD method using a source containing titanium (Ti), and the SiN thin-film 122 may be formed by the ALD method using a source including a compound containing a plurality of silicon (Si) atoms.

Each of the TiN thin-film 121 and the SiN thin-film 122 is provided in plurality or has a plurality of layers. Here, the TiN thin-film 121 may be provided in plurality or have a plurality of layers between the substrate 110 and the SiN thin-film 122 or between two layers of the SiN thin-film 122. For example, as illustrated in FIG. 2, three layers of TiN thin-films 121 may be formed between the substrate 110 and the SiN thin-film 122 or between the two layers of SiN thin-films 122. Here, a plurality of layers of TiN thin-films 121 is formed by repeating an ALD cycle a plurality of times. Although the plurality of layers of TiN thin-films 121 are illustrated to distinguish the TiN thin-film 121 deposited by each ALD cycle, the plurality of laminated TiN thin-films may be integrated with each other.

The SiN thin-film 122 may be formed between two TiN thin-films 121 and formed as a single layer or a plurality of layers. Also, the number of the laminated SiN thin-film 122 may be less than the that of laminated TiN thin-films 121.

A process of forming the above-described lower electrode 120 on the substrate 110 includes a process cycle Cₚ of forming the TiN thin-film 121 and the SiN thin-film 122 on the substrate 110 as illustrated in FIG. 3. Here, the process cycle Cₚ is performed a plurality of times. That is, the process of forming the lower electrode 120 includes a plurality of process cycles Cₚ (Cₚ₁, Cₚ₂, . . . , Cₚₙ₋₁, Cₚₙ), and each of the plurality of process cycles Cₚ (Cₚ₁, Cₚ₂, . . . , Cₚₙ₋₁, Cₚₙ) includes a first cycle C₁ of depositing the TiN thin-film 121 and a second cycle C₂ of depositing the SiN thin-film 122. In other words, each of the plurality of process cycles Cₚ (Cₚ₁, Cₚ₂, . . . , Cₚₙ₋₁, Cₚₙ) includes a step of forming the TIN thin-film 121 and a step of forming the SiN thin-film 122. Also, the step of forming the TIN thin-film 121 includes the first cycle C₁, and the step of forming the SiN thin-film 122 includes the second cycle C₂.

Hereinafter, for convenience of description, the plurality of process cycles Cₚ (Cₚ₁, Cₚ₂, . . . , Cₚₙ₋₁, Cₚₙ) that are sequentially performed are referred to as a first process cycle Cₚ₁, a second process cycle Cₚ₂, n−1st process cycle Cₚₙ₋₁, and nth process cycle Cₚₙ. Here, the character ‘n’ may indicate a last round of the process cycles. Also, the last round n may be changed according to the target performance number of the process cycle, and the target performance number of the process cycle may be changed according to a target thickness of the lower electrode 120 to be manufactured.

The process cycle Cₚ of forming the lower electrode 120 of the capacitor includes the step of forming the TiN thin-film by injecting a source containing titanium (Ti) and a reactant containing nitrogen (N) and the step of forming the SiN thin-film by injecting a source containing silicon (Si) and a reactant containing nitrogen (N), and at least one of the source containing titanium (Ti) and the source containing silicon (Si) is injected a plurality of times.

Here, the injecting of at least one of the source containing titanium (Ti) and the source containing silicon (Si) a plurality of times is injecting the source containing titanium (Ti) in pulses consecutively. Also, while the source containing titanium (Ti) is consecutively injected in pulses, a purge gas or other types of gases may not be injected. Here, the injecting of the source consecutively may represent, e.g., injecting the titanium (Ti) source→the titanium (Ti) source→the titanium (Ti) source→ . . . →the purge gas when the source containing titanium (Ti) is injected, and the purge gas is injected.

Also, the injecting of the source containing silicon (Si) a plurality of times is injecting the source containing silicon (Si) in pulses consecutively. Also, when the source containing silicon (Si) is consecutively injected in pulses, the purge gas or other types of gases may not be injected during consecutive injection. Here, the injecting of the source consecutively may represent injecting the silicon (Si) source→the silicon (Si) source→the silicon (Si) source→ . . . → the purge gas when the source containing silicon (Si) is injected, and the purge gas is injected.

Hereinafter, the process cycle Cₚ will be described in more detail with reference to FIG. 3.

Here, a first process cycle Cₚ₁ will be described as an example.

Referring to FIG. 3, the first process cycle Cₚ₁ includes a first cycle C₁ of depositing the TiN thin-film 121 and a second cycle C₂ of depositing the SiN thin-film 122. Here, the first cycle C₁ is firstly performed before the second cycle C₂.

The first cycle C₁ may include a step of injecting of a first source containing Ti, a step of injecting a purge gas (first purging), a step of injecting a reactant, and a step of injecting a purge gas after stopping the injecting of the reactant (second purging). For example, a gas containing TiCl₄ may be used as the first source containing Ti. Also, a gas containing N, e.g., NH₃, may be used as the reactant. Also, an Ar gas may be used as the purge gas. A TiN atomic layer, i.e., the TiN thin-film 121, is deposited by the ALD method in the first cycle C₁.

The above-described first cycle C₁ of depositing the TiN thin-film 121 may be referred to as a ‘TiN deposition cycle’.

The second cycle C₂ may include a step of injecting a second source including a compound containing a plurality of Si atoms, a step of injecting a purge gas (first purging), a step of injecting a reactant, and a step of injecting a purge gas after stopping the injecting of the reactant (second purging). Here, a precursor including a compound containing a plurality of Si atoms and Cl atoms may be used as the second source. Also, the second source may be in a liquid or gas state.

For example, a precursor containing a Si₂Cl₆(Hexachlorodisilane: HCDS) compound may be used as the second source. Here, the Si₂Cl₆(HCDS) compound contained in the second source includes a Si atom and a Cl atom, and a plurality of Si atoms, i.e., two Si atoms, are contained therein. Alternatively, a source containing at least one precursor of monochlorosilane (MCS: SiH₃Cl), dichlorosilane (DCS: SiH₂Cl₂), trichlorosilane (TCS: SiHCl₃), and hexachlorodisilane (HCDS: Si₂Cl₆) may be used as the second source in addition to the above-described precursor containing Si₂Cl₆(HCDS).

The same gas used in the first cycle C₁ may be used as the reactant and the purge gas. That is, a gas containing nitrogen (N), e.g., a gas containing NH₃, may be used as the reactant, and an argon (Ar) gas may be used as the purge gas. The SiN atomic layer, i.e., the SiN thin-film 122, is deposited by the atomic layer deposition ALD method by the second cycle C₂.

The above-described second cycle C₂ of depositing the SiN thin-film 122 may be referred to as a ‘SiN deposition cycle’.

In the above-described exemplary embodiment, a precursor including a compound containing a plurality of silicon (Si) atoms, e.g., a precursor including at least one compound of Si₂Cl₆(HCDS), monochlorosilane (MCS: SiH₃Cl), dichlorosilane (DCS: SiH₂Cl₂), trichlorosilane (TCS: SiHCl₃), and hexachlorodisilane (HCDS: Si₂Cl₆) is used as the second source for depositing the SiN thin-film 122. Accordingly, a depositing speed of the SiN thin-film 122 may be improved. That is, when the second source is used as with the exemplary embodiment, the deposition speed of the SiN thin-film 122 is improved in comparison with a related art of using a silane (SiH₄) gas as the source

This is because the second source used in the exemplary embodiment includes the Si compound containing a plurality of Si atoms although a source in the related art includes a gas including a SiH₄ compound (Si monatomic compound) containing one Si atom. That is, the compound containing a plurality of Si atoms, e.g., a Si₂Cl₆(HCDS) compound, has reactivity greater than that of the SiH₄ compound that is the Si monatomic compound.

Also, since the deposition speed of the SiN thin-film 122 is improved as with the embodiment, a time for depositing the lower electrode 120 having a target thickness may be reduced in comparison with the related art.

In the exemplary embodiment, when the above-described first cycle C₁ and second cycle C₂ are performed, the performed number T₁ of first cycles C₁ contained in one process cycle Cₚ is greater than the performed number T₂ of second cycles C₂. That is, the performed number T₁ of first cycles C₁ is a plurality of times, and the performed number T₂ of second cycles C₂ is less than the performed number T₁ of first cycles C₁. Here, the performed number T₂ of second cycles C₂ may be a plurality of times according to the performed number T₁ of first cycles C₁. Also, when each of the first and second cycles C₁ and C₂ is performed a plurality of times, the first cycle C₁ is performed a plurality of times consecutively, and then the second cycle C₂ is performed a plurality of times consecutively.

Here, a ratio (T₁:T₂) of the performed number T₁ of first cycles C₁ to the performed number T₂ of second cycles C₂ is adjusted to be 1:1 to 4:1 (T₁:T₂=1:1 to 4:1). More preferably, the ratio (T₁:T₂) of the performed number T1 of first cycles C₁ to the performed number T₂ of second cycles C₂ is adjusted to be 3:1 to 4:1 (T₁:T₂=3:1 to 4:1).

As described above, the first cycle C₁ may be referred to as a ‘TiN deposition cycle’, and the second cycle C₂ may be referred to as a ‘SiN deposition cycle’. Here, the ‘ratio (T₁:T₂) of the performed number T1 of first cycles C₁ to the performed number T₂ of second cycles C₂’ may be the ‘ratio (T₁:T₂) of the performed number T₁ of TiN deposition cycles C₁ to the performed number T₂ of SiN deposition cycles C₂’.

Also, the TiN deposition cycle may be referred to as a ‘step of forming a TiN thin-film’, and the SiN deposition cycle may be referred to as a ‘step of forming a SiN thin-film’. Thus, the ratio (T₁:T₂) of the performed number T₁ of the step of forming the TiN thin-film to the performed number T₂ of the step of the forming the SiN thin-film is adjusted to 1:1 to 4:1, more preferably 3:1 to 4:1.

Hereinafter, for convenience of description, ‘the ratio (T₁:T₂) of the performed number T₁ of first cycles C₁ to the performed number T₂ of second cycles C_{2’} is referred to as ‘the ratio (T₁:T₂) of the performed number of the first and second cycles’.

More specifically, a case in which the ratio (T₁:T₂) of the performed number of the first and second cycles is 3:1 will be described as an example with reference to FIG. 3. Referring to FIG. 3, each of the plurality of process cycles Cₚ (Cₚ₁, Cₚ₂, . . . , Cₚₙ₋₁, Cₚₙ) may include the first and second cycles C₁ and C₂, and here, the ratio (T₁:T₂) of the performed number of the first and second cycles may be 3:1.

More specifically, for example, each of the plurality of process cycles Cₚ (Cₚ₁, Cₚ₂, . . . , Cₚₙ₋₁, Cₚₙ) may include three first cycles C₁ and one second cycle C₂ as illustrated in FIG. 3. In case of the first process cycle Cₚ₁, for example, the first cycle C₁ is performed consecutively three times. Thus, as illustrated in FIG. 2, three layers of TiN thin-films 121 are consecutively deposited on the substrate 110. When the three first cycles C₁ are completed, the second cycle C₂ is performed one time. Thus, one layer of SiN thin-film 122 is deposited on the TiN thin-film 121. As described above, since the first cycle C₁ is performed three times consecutively and then the second cycle C₂ is performed one time, the ratio (T₁:T₂) of the performed number of the first and second cycles may be 3:1.

When the second cycle C₂ of the first process cycle Cₚ₁ is finished, the second process cycle Cₚ₂ is performed. Here, the second process cycle Cₚ₂ may be performed with the same ratio as the ratio (T₁:T₂) of first and second cycles performed in the first process cycle Cₚ₁. That is, when the second process cycle Cₚ₂ is performed, the ratio (T₁:T₂) of the performed number of the first and second cycles is 3:1.

When the second cycle C₂ of the second process cycle Cₚ₂ is finished, a next process cycle (Cₚ₃, . . . ,Cₚₙ₋₁, Cₚₙ) is performed. Here, the process cycle is performed until the target number n to be performed as with FIG. 3.

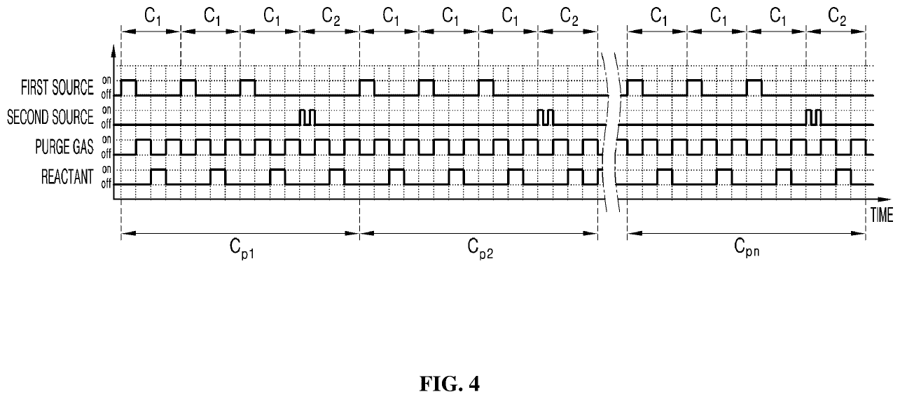

FIG. 4 is a conceptual view for explaining the method for forming the lower electrode by the method in accordance with a modified example of an exemplary embodiment.

The second source in the second cycle C₂ is injected one time in an exemplary embodiment. However, the exemplary embodiment is not limited thereto. For example, the second source may be injected two times as with the modified example in FIG. 4. In other words, the second cycle C₂ in accordance with the modified example of an exemplary embodiment may be performed in an order of ‘1-st second source injection—2-nd second source injection-purge gas injection-reactant injection-purge gas injection’. Here, the 2-nd second source injection may be performed with a time difference after the 1-st second source injection. In other words, the second source is injected in pulses. Also, a sum of an injected amount of the 1-st second source injection and an injected amount of the 2-nd second source injection may be adjusted to a target injected amount of the second source to be injected in one second cycle C₂.

In the above-described example, the second source is divided and injected two times. However, the second source may be divided into more than two times, and ‘purge gas injection-reactant injection-purge gas injection’ may be performed after last second source injection.

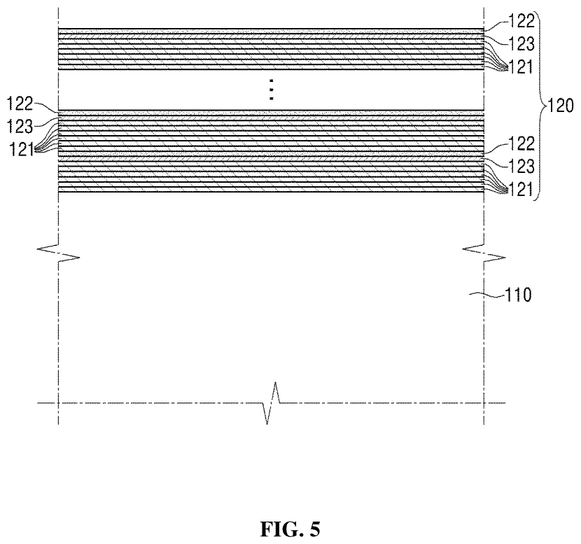

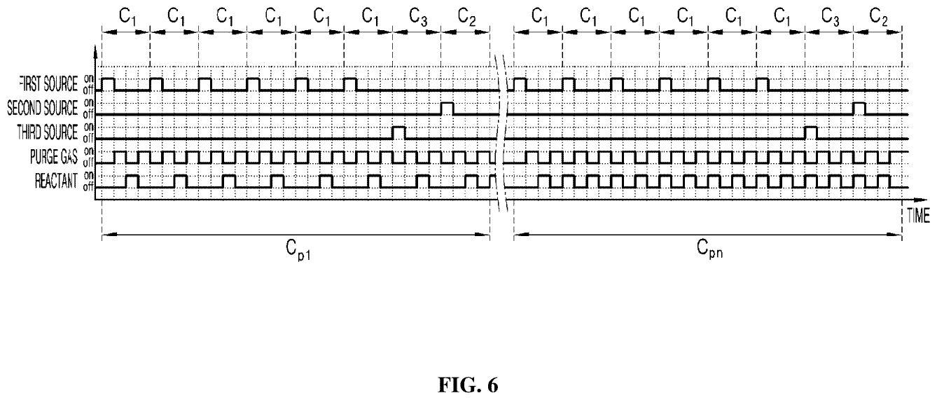

FIG. 5 is a view illustrating the lower electrode formed on the substrate by a method in accordance with another exemplary embodiment. FIG. 6 is a conceptual view for explaining the method for forming the lower electrode by the method in accordance with another exemplary embodiment.

In an exemplary embodiment, the precursor including the compound containing a plurality of Si atoms as the source, i.e., the precursor including the Si₂Cl₆(HCDS) compound, is used in the depositing of the SiN thin-film 122. That is, the SiN thin-film 122 in accordance with an exemplary embodiment is a thin-film deposited by using the second source including the compound containing a plurality of Si atoms.

However, the exemplary embodiment is not limited thereto. For example, the SiN thin-film 123 may be deposited by using a source (hereinafter, referred to as a third source) different from the second source. Here, the second cycle C₂ of depositing the SiN thin-film 122 using the second source and a cycle of depositing the SiN thin-film 123 using the third source are performed as separate cycles. Thus, the cycle of depositing the SiN thin-film 123 using the third source is referred to as a third cycle C₃.

Referring to FIG. 5, the lower electrode 120 may include a TiN thin-film 121 and SiN thin-films 122 and 123 deposited on the TiN thin-film 121.

Here, one of the SiN thin-films 122 and 123 is the thin-film 123 formed by the third cycle C₃, and the rest is the thin-film 122 formed by the second cycle C₂. Here, the third source used in the third cycle C₃ may include a Si monatomic compound. More specifically, the third source may be a gas containing silicon (Si) and hydrogen (H), e.g., a silane (SiH₄) gas. Thus, one of the SiN thin-films 122 and 123 is the thin-film 123 formed by using the third source that is a gas containing a SiH₄ compound or made of the SiH₄ compound that is a Si monatomic compound, and the rest is the thin-film 122 formed by using the second source including a gas including a compound containing a plurality of Si atoms, e.g., a precursor including a Si₂Cl₆(HCDS) compound.

Also, in the lower electrode 120, the number of the laminated SiN thin-film 122 and 123 formed by the second and third cycles C₂ and C₃ may be less than that of the laminated TiN thin-films 121.

Referring to FIG. 6, the process cycle Cₚ (Cₚ₁, Cₚ₂, . . . , Cₚₙ₋₁, Cₚₙ) in accordance with another exemplary embodiment includes a first cycle C₁ of depositing the TiN thin-film 121 and second and third cycles C₂ and C₃ of depositing the SiN thin-films 122 and 123.

Here, since the first and second cycles C₁ and C₂ are the same as those in an exemplary embodiment, a description thereof will be omitted.

The third cycle C₃ may include a step of injecting a third source that is a gas containing a Si monatomic compound, a step of injecting a purge gas (first purging), a step of injecting a reactant, and a step of injecting a purge gas after stopping the injecting of the reactant (second purging).

Here, as described above, a gas containing Si and H, i.e., a silane (SiH₄) gas may be used as the third source. Also, the reactant and the purge gas may be the same as those used in the first and second cycles C₁ and C₂. That is, a gas containing N, e.g., NH₃, may be used as the reactant, and an Ar gas may be used as the purge gas. A SiN atomic layer, i.e., the SiN thin-film 123, is deposited by the ALD method in the third cycle C₃.

When the process cycle Cₚ (Cₚ₁, Cₚ₂, . . . , Cₚₙ₋₁, Cₚₙ) including the first to third cycles C₁ to C₃ is performed, the first cycle C₁ is firstly performed to deposit the TiN thin-film 121, and then the second and third cycles C₂ and C₃ are performed to deposit the SiN thin-films 122 and 123. Here, when the SiN thin-films 122 and 123 are deposited, the third cycle C₃ is firstly performed, and then the second cycle C₂ is performed. In other words, the SiN thin-film 123 is deposited by using the third source including silane (SiH₄), and then the SiN thin-film 122 is deposited by using the second source including a compound containing a plurality of Si atoms. That is, in yet another exemplary embodiment, the process cycle Cₚ is performed in an order of ‘first cycle C₁—third cycle C₃—second cycle C₂’.

Also, when the second and third cycles C₂ and C₃ are performed, a ratio (T₂:T₃) of the performed number of the second cycle C₂ to that of the third cycle C₃ is adjusted to 1:3 to 3:1 (T₂:T₃=1:3 to 3:1).

Here, since the second cycle C₂ is performed after the third cycle C₃ is performed, the third cycle C₃ may be referred to as a step of forming a first SiN thin-film, and the second cycle C₂ may be referred to as a step of forming a second SiN thin-film. Thus, when the SiN thin-film is formed, the ratio (T₂:T₃) of the performed number T₂ of the step of forming the second SiN thin-film to the performed number T₃ of the step of forming the first SiN thin-film may be adjusted to 1:3 to 3:1.

Also, when the first to third cycles C₁ to C₃ are performed, a ratio (T₁:T₂₊₃) of the performed number T₁ of the first cycle C₁ to the number T₂-3 that is a sum of the performed number T₂ of the second cycle C₂ and the performed number T₃ of the third cycle C₃ is adjusted to 1:1 to 4:1, preferably 3:1 to 4:1.

Hereinafter, for convenience of description, ‘the ratio (T₂:T₃) of the performed number T₂ of the second cycle C₂ to the performed number T₃ of the third cycle C_{3’} is referred to as ‘the ratio (T₂:T₃) of the performed number of the second and third cycles’.

Also, ‘the ratio (T₁:T₂₊₃) of the performed number T₁ of the first cycle to the performed number T₂₊₃ that is a sum of the performed number T₂ of the second cycle and the performed number T₃ of the third cycle’ is referred to as ‘the ratio (T₁:T₂₊₃) of the performed number T₁ of the TiN deposition cycle to the performed number T₂₊₃ of the SiN deposition cycles C₂ and C₃’.

More specifically, a case in which the ratio (T₁:T₂₊₃) of the performed number T₁ of the TiN deposition cycle to the performed number T₂₊₃ of the SiN deposition cycles C₂ and C₃ is 3:1 is described as an example with reference to FIG. 6. Also, a case in which the ratio (T₂:T₃) of the performed number of the second and third cycles C₂ and C₃ is 1:1 is described as an example. Thus, a ratio (T₁:T₂:T₃) of the performed number T₁ of the first cycle C₁, the performed number T₂ of the second cycle C₂, and the performed number T₃ of the third cycle C₃ is 6:1:1.

Each of the plurality of process cycles Cₚ (Cₚ₁, Cₚ₂, . . . , Cₚₙ₋₁, Cₚₙ) may include six first cycles C₁, one second cycle C₂, and one third cycle C₃ as illustrated in FIG. 6. In case of the first process cycle Cₚ₁, for example, the first cycle C₁ is performed consecutively six times. Thus, as illustrated in FIG. 5, six layers of TiN thin-films 121 are consecutively deposited on the substrate 110. When the six first cycles C₁ are finished, the third cycle C₃ is performed one time. That is, the ALD using the third source including silane (SiH₄) is performed one time. Thus, one layer of SiN thin-film 123 is deposited on the TiN thin-film 121.

When the third cycle C₃ is finished, the second cycle C₂ is performed one time. That is, the ALD using the second source including a precursor including a compound containing a plurality of Si atoms, e.g., a precursor including a Si₂Cl₆(HCDS) compound, is performed one time. Accordingly, the SiN thin-film 122 using the second source including the Si₂Cl₆(HCDS) precursor is deposited on the SiN thin-film 123 deposited by using the third source including silane (SiH₄).

When six first cycles C₁, one third cycle C₃, and one second cycle C₂ are sequentially performed, a next process cycle (Cₚ₂, . . . ,Cₚₙ₋₁, Cₚₙ) is performed in the same manner. Here, when each process cycle (Cₚ₂, . . . , Cₚₙ₋₁, Cₚₙ) is performed, a ratio of the performed number T₁, T₂, and T₃ of the first to third cycles C₁ to C₃ is the same. Thus, the ratio (T₁:T₂:T₃) of the performed number T₁ of the first cycle C₁, the performed number T₂ of the second cycle C₂, and the performed number T₃ of the third cycle C₃ is adjusted to 6:1:1. That is, a ratio (T₁:T₂₊₃) of the performed number T₁ of the TiN deposition cycle to the performed number T₂₊₃ of the SiN deposition cycles C₂ and C₃ is adjusted to 3:1 in each process cycle Cₚ (Cₚ₁, Cₚ₂, . . . ,Cₚₙ₋₁, Cₚₙ). Also, a ratio (T₂:T₃) of the performed number of the second and third cycles C₂ and C₃ is adjusted to 1:1 in each process cycle.

As described above, the first cycle C₁ is a cycle for depositing the TiN thin-film 121, and the second and third cycles C₂ and C₃ are cycles for depositing the SiN thin-films 122 and 123. Also, in another exemplary embodiment, the process cycle Cₚ is performed in an order of the first cycle C₁, the third cycle C₃, and the second cycle C₂. Thus, the first cycle C₁ may be referred to as a ‘TiN deposition cycle’, the third cycle C₃ may be referred to as a ‘first SiN deposition cycle’, and the second cycle C₂ may be referred to as a ‘second SiN deposition cycle’.

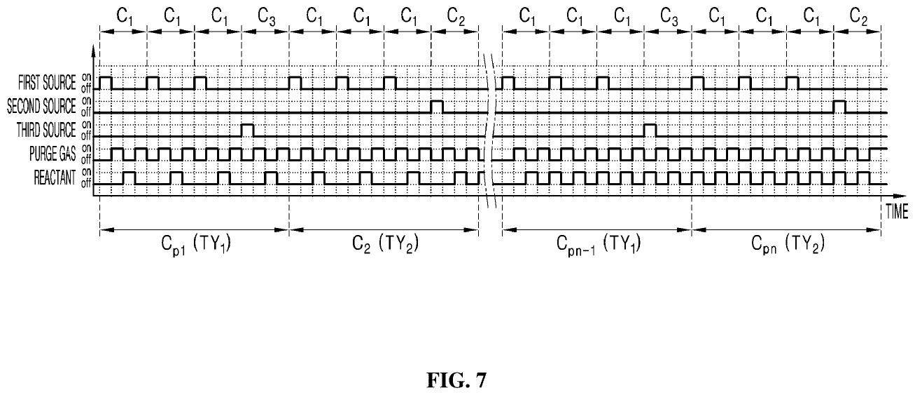

FIG. 7 is a conceptual view for explaining a method for forming a lower electrode by a method in accordance with yet another exemplary embodiment.

The plurality of process cycles Cₚ (Cₚ₁, Cₚ₂, . . . ,Cₚₙ₋₁, Cₚₙ) are performed in the same manner in an exemplary embodiment and another exemplary embodiment. However, the exemplary embodiment is not limited thereto. For example, a portion of the plurality of process cycles Cₚ (Cₚ₁,Cₚ₂, . . . ,Cₚₙ₋₁, Cₚₙ) may be performed in a different manner.

That is, the method of forming the lower electrode in accordance with the yet another exemplary embodiment include a process cycle of a first type TY₁ using a SiH₄ gas as a third source and a process cycle of a second type TY₂ using a source including a compound precursor containing a plurality of Si atoms, i.e., a second source when the SiN thin-film is deposited. Also, the process cycle of the first type TY₁ and the process cycle of the second type TY₂ are alternately performed a plurality of times.

First, each of the process cycle of the first type TY₁ and the process cycle of the second type TY₂ will be described.

The process cycle of the first type TY₁ includes a first cycle C₁ and a third cycle C₃. That is, the process cycle of the first type TY₁ includes the first cycle C₁ of depositing the TiN thin-film and the third cycle C₃ of depositing the SiN thin-film by using the third source including SiH₄. Here, the ratio (T₁:T₃) of the performed number T₁ of the first cycle C₁ to the performed number T₃ of the third cycle C₃ is adjusted to 1:1 to 4:1, preferably 3:1 to 4:1. That is, the ratio (T₁:T₃) of the performed number of the first and third cycles may be 1:1 to 4:1, preferably 1:1 to 4:1.

The process cycle of the second type TY₂ includes a first cycle C₁ and a second cycle C₂. That is, the process cycle of the second type TY₂ includes the first cycle C₁ of depositing the TiN thin-film and the second cycle C₂ of depositing the SiN thin-film by using the second source including a compound precursor containing a plurality of Si atoms. Here, the ratio (T₁:T₂) of the performed number of the first and second cycles may be 1:1 to 4:1, preferably 3:1 to 4:1.

The process cycle of the first type TY₁ and the process cycle of the second type TY₂ are alternately performed a plurality of times. Also, the first process cycle Cₚ₁ is the process cycle of the first type TY₁. Thus, as illustrated in FIG. 7, the first process cycle Cₚ₁ may be performed as the first type TY₁, the second process cycle Cₚ₂ may be performed as the second type TY₂, the third process cycle Cₚ₃ may be performed as the first type TY₁, the fourth process cycle Cₚ₄ may be performed as the second type TY₂, the n−1st process cycle Cₚₙ₋₁ may be performed as the first type TY₁, and the nth process cycle Cₚₙ may be performed as the second type TY₂.

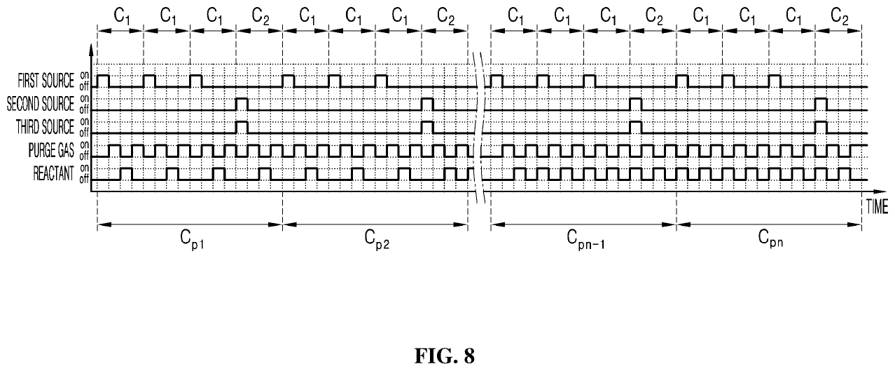

FIG. 8 is a conceptual view for explaining the method for forming the lower electrode by the method in accordance with a modified example of yet another exemplary embodiment.

In the above-described yet another exemplary embodiment, the second cycle C₂ of injecting the second source and the third cycle C₃ of injecting the third source are performed in different process cycles.

However, the exemplary embodiment is not limited thereto. For example, the second source and the third source may be simultaneously injected as with the modified example in FIG. 8. That is, the second cycle C₂ in accordance with the modified example of yet another exemplary embodiment may be performed in an order of ‘second and third source injection-purge gas injection-reactant injection-purge gas injection’ as illustrated in FIG. 8. Here, the second source and the third source may be separately stored and simultaneously injected toward the substrate 110. However, the exemplary embodiment is not limited thereto. For example, the second source and the third source may be mixed and stored, and the mixed gas may be injected toward the substrate 110.

Also, when the SiN thin-film is deposited in an exemplary embodiment to yet another exemplary embodiment and the modified examples, only the second source including the compound precursor containing a plurality of Si atoms is used alone, or the second source and the third source including silane (SiH₄) are used together. However, the exemplary embodiment is not limited thereto. For example, the SiN thin-film may be deposited by using the third source including silane (SiH₄) instead of using the second source.

In this case, the process cycle Cₚ includes the first cycle C₁ of depositing the TiN thin-film 121 and the third cycle C₃ of depositing the SiN thin-film using the third source including silane (SiH₄). Here, the process cycle may not include the second cycle C₂.

Here, injection of the third source in the third cycle C₃ may be divided into a plurality of times, e.g., two times. That is, the third cycle C₃ may be performed in an order of ‘1-st third source injection—2-nd third source injection—purge gas injection—reactant injection—purge gas injection’. Here, the 2-nd third source injection may be performed with a time difference after the 1-st third source injection. In other words, the third source is injected in pulses. Also, a sum of an injected amount of the 1-st third source injection and an injected amount of the 2-nd third source injection may be adjusted to a target injected amount of the third source to be injected in one third cycle C₃.

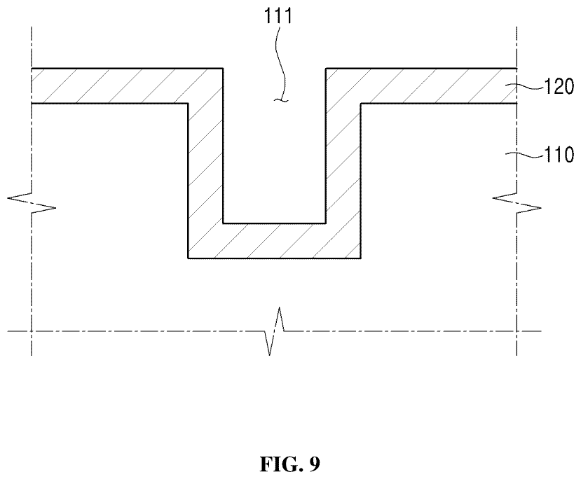

FIG. 9 is a view illustrating the lower electrode formed on the substrate by a method in accordance with exemplary embodiments.

In the above description, the lower electrode 120 for a capacitor is formed on the flat substrate 110. However, the exemplary embodiment is not limited thereto. For example, as illustrated in FIG. 9, a capacitor may be manufactured by forming the lower electrode 120 on the substrate 110 having a trench 111 by the method in accordance with exemplary embodiments.

When the lower electrode 120 is formed on the substrate 110 having the trench 111, step coverage is improved by using the method in accordance with exemplary embodiments in comparison with a case of the related art. That is, In the lower electrode 120 formed on the substrate 110 having the trench 111, a thickness of the lower electrode deposited on an inner side surface surrounding the trench 111, a thickness of the lower electrode deposited on a bottom surface, and a thickness of the lower electrode deposited on a top surface are uniformed in comparison with the related art.

In other words, the step coverage (%) may be calculated as a ratio of a deposition thickness THE formed on the bottom surface in the trench 111 to a deposition thickness THₜ formed on the top surface of the substrate 110. That is, the step coverage (%) is a ratio obtained by dividing a thickness THE of the lower electrode 120 deposited on the bottom surface partitioning the trench 111 by a thickness THₜ of the lower electrode 120 deposited on the top surface of the substrate 110 corresponding to the outside of the trench 111 (refer to equation 1).

Step coverage (%)=TH_{b}/THₜ×100% [Equation 1]

The step coverage is improved in a case of using the method in accordance with exemplary embodiments in comparison with the related art. That is, when the lower electrode 120 is prepared by laminating the TiN thin-film and the SiN thin-film on the substrate 110 having the trench 111, the step coverage is improved in a case of depositing the SiN thin-film by using a gas including a compound containing a plurality of Si atoms, e.g., a gas including a Si₂Cl₆(HCDS) compound, as a source as with exemplary embodiments in comparison with a case of using silane (SiH₄) gas as a source as with the related art. This is because reactivity of the gas including the compound containing a plurality of Si atoms such as the Si₂Cl₆(HCDS) gas, is higher than that of the silane (SiH₄) gas, and thus, a deposition speed of the SiN thin-film 122 is improved.

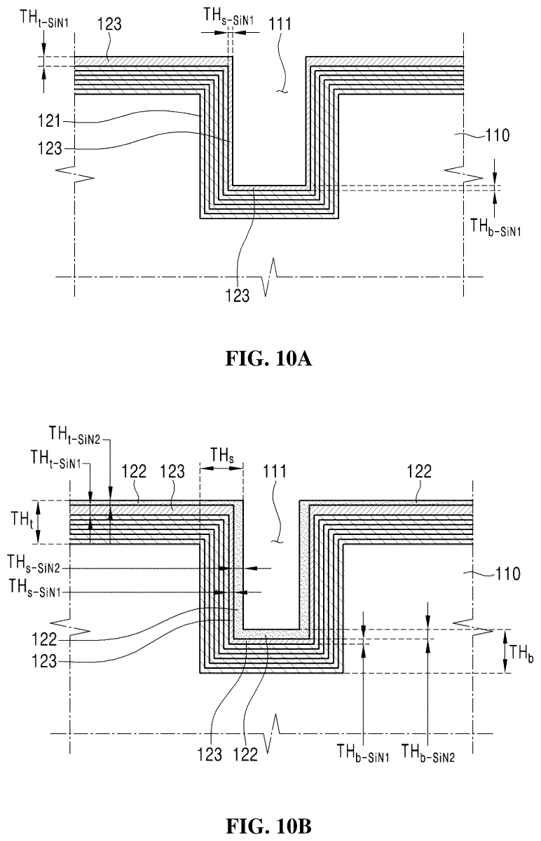

FIGS. 10A and 10B are views illustrating a state in which the TiN thin-film and the SiN thin-film are laminated on the substrate having the trench by the method in accordance with another exemplary embodiment.

Here, FIG. 10A shows a state in which the first cycle C₁ and the third cycle C₃ of the first process cycle are performed, and FIG. 10B shows a state in which the second cycle C₂ is performed after the first and third cycles C₁ and C₃ are finished.

When the lower electrode 120 is formed on the substrate 110 having the trench 111 to prepare the capacitor 100, the step coverage may be more effectively improved when the lower electrode 120 is formed in accordance with another exemplary embodiment among an exemplary embodiment to yet another exemplary embodiment.

This will be described in more detail with reference to FIGS. 6 and 10. Firstly, the first process cycle Cₚ₁ is performed to form the lower electrode 120 on the substrate 110 having the trench 111. To this end, e.g., the first process cycle Cₚ₁ is performed consecutively six times as with FIG. 6. Thus, as illustrated in FIG. 10A, the six layers of TiN thin-films 121 are consecutively deposited on the substrate 110.

When the six first cycles C₁ are finished, the third cycle C₃ is performed one time. That is, the ALD using the third source including silane (SiH₄) is performed one time. Thus, the one layer of SiN thin-film 123 (hereinafter, referred to as the first SiN thin-film 123) is deposited on the TiN thin-film 121. Here, as illustrated in FIG. 10A, a thicknesses THₛ₋ₛᵢₙ₁ and TH_{b-sin1} of the first SiN thin-film 123 formed on an inner side surface and a bottom surface of the TiN thin-film 121 surrounding the trench 111 is less than a thickness THₜ₋ₛᵢₙ₁ of the first SiN thin-film 123 deposited on a top surface of the TiN thin-film 121 outside the trench 111. This may be due to a slow deposition speed of SiH₄.

When the third cycle C₃ is finished, the second cycle C₂ is performed one time. That is, the ALD using the second source including a gas including a compound precursor containing a plurality of Si atoms, e.g., the Si₂Cl₆(HCDS) compound precursor, is performed one time. Accordingly, the SiN thin-film (second SiN thin-film 122) using the second source including the Si₂Cl₆(HCDS) precursor is deposited on the first SiN thin-film 123 deposited by using the third source made of a SiH₄ compound that is a Si monatomic compound or the third source including a SiH₄ compound. Here, as illustrated in FIG. 10B, in the second SiN thin-film 122, a thickness THₛ₋ₛᵢₙ₂ and TH_{b-sin2} of the second SiN thin-film 122 formed on the inner side surface and the bottom surface surrounding the trench 111 is greater than a thickness THₜ₋ₛᵢₙ₂ formed in an area corresponding to the top surface of the substrate 110. This may be due to a slow deposition speed of SiH₄.

This is because the first SiN thin-film 123 formed by using the source of SiH₄ interrupts the second SiN thin-film 122 from being deposited on a surface thereof. Here, the second SiN thin-film 122 is formed by using the second source including the gas including a compound precursor containing a plurality of Si atoms, e.g., the Si₂Cl₆(HCDS) precursor. Also, the first SiN thin-film 123 is formed relatively thick on the top surface of the substrate 110 and relatively thin on the inner side surface and bottom surface in the trench 111. As the thickness increases, force that interrupts or hinders the deposition of the second SiN thin-film 122 may increase. Also, in comparison with a SiH₄ compound gas having one Si atom, the second source including the compound precursor containing a plurality of Si atoms may descend more quickly and easily to a deep depth in the trench 111.

Accordingly, when the second SiN thin-film 122 is formed on the first SiN thin-film 123, the second SiN thin-film 122 may be deposited on the top surface of the first SiN thin-film 123 with a relatively small thickness THₜ₋ₛᵢₙ₂, and the second SiN thin-film 122 may be deposited on the inner side surface and the bottom surface of the first SiN thin-film 123 in the trench 111 with a relatively great thickness.

When the first process cycle Cₚ₁ performed in the order of the first cycle C₁, the third cycle C₃, and the second cycle C₂ is finished, as illustrated in FIG. 10B, a thickness of the thin-film formed on the top surface of the substrate 110 is equal or similar to that of the thin-film formed on the inner side surface and the bottom surface of the substrate 110 in the trench 111.

Thus, when the lower electrode 120 is formed by repeating the process cycle a plurality of times, the lower electrode 120 having excellent step coverage may be prepared.

Table 1 shows results of forming the lower electrode 120 on the substrate 110 having the trench 111 and calculating the step coverage in accordance with an exemplary embodiment and a comparative example.

TABLE 1

| Classification | Comparative example | Exemplary embodiment |
|---|---|---|
| Step coverage (%) | 75.4% | 77.2% |

For an experiment, two substrates 110 each having the trench 111 are prepared, the lower electrode 120 is formed on one substrate 110 by a method in accordance with the comparative example, and the lower electrode 120 is formed on another substrate 110 by the method in accordance with an exemplary embodiment.

All of the lower electrodes 120 in accordance with the comparative example and an exemplary embodiment are formed on the substrate 110 by depositing the TiN thin-film 121 and the SiN thin-film 122 in the ALD method. Also, the ratio (T₁:T₂) of the performed number of the first and second cycles in accordance with the comparative example and an exemplary embodiment is 3:1. In addition, the first source, the purge gas, and the reactant used for the first cycle C₁ or deposition of the TiN thin-film 121 is equally used in the comparative example and an exemplary embodiment. That is, in the comparative example and an exemplary embodiment, a TiCl₄ gas is used as the first source, a NH₃ gas is used as the reactant, and an Ar gas is used as the purge gas.

Here, the second source used for the second cycle C₂ or deposition of the SiN thin-film 122 is differently used in the comparative example and an exemplary embodiment. That is, the comparative example uses the silane (SiH₄) gas as the second source, and an exemplary embodiment uses the gas including the Si₂Cl₆(HCDS) precursor as the second source.

In addition, a NH₃ gas is equally used as the reactant used in the deposition of the SiN thin-film 122 or the second cycle C₂, and the Ar gas is equally used as the purge gas in the comparative example and an exemplary embodiment.

Also, in the comparative example and an exemplary embodiment, the performed number T₁ of the first cycle C₁ and the performed number T₂ of the second cycle C₂ are the same, and a ratio of the performed number of the first and second cycles is equally 3:1.

The lower electrode is formed by the above-described method, and the step coverage is calculated by a method as in Equation 1.

Referring to Table 1, the step coverage of the lower electrode formed by the method in accordance with an exemplary embodiment is greater than that of the lower electrode formed by the method in accordance with the comparative example. This is because the deposition speed of the SiN thin-film 122 by using the gas including the Si₂Cl₆(HCDS) compound as the source in accordance with an exemplary embodiment is faster than that of the comparative example although the SiN thin-film 122 is deposited by using the silane (SiH₄) gas as the source in accordance with the comparative example.

The forming of the lower electrode 120 of the capacitor by the method in accordance with exemplary embodiments is described above. However, the upper electrode 140 may be formed by the method in accordance with exemplary embodiments, or the lower electrode 120 and the upper electrode 140 may be formed by the method in accordance with exemplary embodiments.

As described above, in the exemplary embodiments, when at least one of the lower electrode 120 and the upper electrode 140 of the capacitor 100 is formed by laminating the TiN thin-film 121 and the SiN thin-film 122, the SiN thin-film 122 is deposited by using the source including the compound precursor containing a plurality of Si atoms. Thus, the deposition speed of the SiN thin-film 122 may be improved, and the step coverage of the thin-film may be improved.

In accordance with the exemplary embodiment, when at least one of the lower electrode and the upper electrode of the capacitor is formed by laminating the TiN thin-film and the SiN thin-film, the SiN thin-film is formed by using the source containing the plurality of Si atoms. Thus, the deposition speed of the SiN thin-film may be improved, and the step coverage of the thin-film may be improved.

Although the exemplary embodiments of the present invention have been described, it is understood that the present invention should not be limited to these embodiments but various changes and modifications can be made by one ordinary skilled in the art within the spirit and scope of the present invention as hereinafter claimed.

1. A method for forming a capacitor electrode, the method comprising:
forming a TiN thin-film by injecting a source containing titanium (Ti) and a reactant containing nitrogen; and
forming a SiN thin-film by injecting a source containing silicon (Si) and a reactant containing nitrogen,
wherein at least one of the source containing titanium (Ti) and the source containing silicon (Si) is injected a plurality of times.

2. The method for forming a capacitor electrode of claim 1, wherein the forming of the TiN thin-film and the forming of the SiN thin-film are consecutively performed.

3. The method for forming a capacitor electrode of claim 2, wherein the forming of the TiN thin-film is consecutively performed more times than the forming of the SiN thin-film.

4. The method for forming a capacitor electrode of claim 2, wherein a ratio (T1:T2) of the performed number (T1) of the forming of the TiN thin-film to the performed number (T2) of the forming of the SiN thin-film is adjusted to 1:1 to 4:1.

5. The method for forming a capacitor electrode of claim 1, wherein the source containing silicon (Si) is a silicon (Si) gas containing hydrogen (H) or a silicon (Si) precursor containing chlorine (Cl), or
a mixed gas in which the silicon (Si) gas containing hydrogen (H) and the silicon (Si) precursor containing chlorine (Cl) are mixed.

6. The method for forming a capacitor electrode of claim 5, wherein the silicon (Si) precursor containing chlorine (Cl) is hexachlorodisilane (HCDS: Si2Cl6) or dichlorosilane (DCS: SiH2Cl2), and
the silicon (Si) gas containing hydrogen (H) is silane (SiH₄).

7. The method for forming a capacitor electrode of claim 5, wherein the forming of the SiN thin-film comprises:
forming a first SiN thin-film by injecting the silicon (Si) gas containing hydrogen (H); and
forming a second SiN thin-film by injecting the silicon (Si) precursor containing chlorine (Cl).

8. The method for forming a capacitor electrode of claim 7, wherein a ratio of the performed number of the forming of the second SiN thin-film to the performed number of the forming of the first SiN thin-film is adjusted to 1:3 to 3:1.

9. The method for forming a capacitor electrode of claim 1, wherein injecting a purge gas is added between injecting different kinds of gases.
